(19) United States
(12) Patent Application Publication
(10) Pub. No.: US 2005/0023659 A1
(43) Pub. Date: Feb. 3, 2005

(54) Semiconductor chip package and stacked module having a functional part and packaging part arranged on a common plane

(76) Inventors: Sang-Yeop Lee, Cheonan-si (KR); Cheul-Joong Youn, Seoul (KR)

Correspondence Address: HARNESS, DICKEY & PIERCE, P.L.C., P.O. BOX 8910, RESTON, VA, 20195, US

(21) Appl. No.: 10/897,098

(22) Filed: Jul. 23, 2004

(30) Foreign Application Priority Data
Jul. 31, 2003 (KR) 2003-53078

(51) Int. Cl. H01L 23/02

(52) U.S. Cl. 257/678

(57) ABSTRACT

A semiconductor chip package may include functional and packaging parts, which may be separated into first and second areas respectively, and designated only for a specific type of semiconductor material. The first area may be designated only for functional material, while the second area may be designated only for packaging material. The first area may include a semiconductor chip and/or passive elements, while the second area may include packaging material for example, solder and/or contact pads.

### BACKGROUND OF THE INVENTION

This application claims the priority of Korean Patent Application No. 2003-53078, filed on Jul. 31, 2003, in the Korean Intellectual Property Office, the disclosure of which is incorporated herein in its entirety by reference.

1. Field of the Invention

The present invention relates to a semiconductor chip package and stacked module, which may be formed by a plurality of semiconductor chip packages. The semiconductor chip package or stacked module may have a functional part on which a semiconductor chip is mounted, and a packaging part to which a bump may be placed for connecting the semiconductor chip to an external terminal.

2. Description of the Related Art

Packaging technologies for integrated circuits in the semiconductor industry may be developed to miniaturize and enhance packaging reliability. As electronic devices become smaller and more integrated, a semiconductor chip package, which may be used in these devices, may be miniaturized and lightened. A stacked module, which may be formed by stacking a plurality of semiconductor packages, may be developed to address processing speed and capacity limitations, which may be associated with a single semiconductor package, and which may be due to limitations in the packaging process.

A semiconductor chip package may be categorized based on packaging and/or lead types. For example, a dual in-line package (DIP), a quad flat package (QFP), a thin small outline package (TSOP), a ball grid array (BGA) package, and a bottom leaded package (BLP) are some exemplary semiconductor chip package types. Among these types, the BGA package for example, may utilize a spherical solder ball, instead of an outer lead, which may be arranged on a back surface of a board to which the semiconductor chip may be attached.

FIG. 1 is a longitudinal sectional view illustrating a structure of a ball grid array (BGA) package according to a conventional semiconductor chip package.

Referring to FIG. 1, a conventional BGA package may include a semiconductor chip 10, which may be attached to an upper surface of a first circuit board 2 by an insulating adhesive 4. A chip pad 10a may be formed on the upper surface of the semiconductor chip 10, and may be electrically connected to a metal wiring layer on the first circuit board 10, by bonding wires 12. The semiconductor chip 10 and bonding wires 12 may be protected from external shock by a molding part 14, which may be formed from a resin material such as an epoxy molding compound (EMC). A metal bump 18 may be formed from a solder ball and attached to a lower surface of the first circuit board 2. The metal bump 18 may be electrically connected to the semiconductor chip 10 by contact 16, and may contact a contact pad 24, which may be formed on a second circuit board 22 of an external terminal so as to electrically connect the semiconductor chip 10 to the external terminal. For example, a power supply terminal may be formed on a mother board or another semiconductor chip package, and may be formed in a stacked module.

A conventional BGA package for example, may include a functional part attached to a semiconductor chip 10, and may also include a packaging part on which a metal bump 18 may be formed. The functional and packaging parts may be arranged vertically to reduce the amount of packaging area required for a semiconductor chip package. A conventional BGA package for example, may include a reduced body area when compared to a conventional QFP-type package. A conventional BGA package may also have no lead deformation unlike a conventional QFP-type package.

If a semiconductor chip package is applied to a stacked module, which may include a plurality of semiconductor chip packages, then a BGA package for example, may have an increased thickness due to a vertical arrangement of corresponding functional and packaging parts as illustrated in FIG. 1 for example, and thus may create a height problem when attempting to mount a BGA package in thin products. The potential height problem, which may be realized when mounting a BGA package for example, may be alleviated by forming a specific sized solder ball, for example forming a small metal bump, however a shock resistant characteristic of the package may be degraded by reducing the size of the solder ball.

A semiconductor integrated circuit chip may include a semiconductor substrate formed of silicon. A silicon chip and a metal bump may have different thermal expansion coefficients, thus thermal stress may occur in the semiconductor chip package given a change in temperature. A conventional semiconductor chip package having a functional part to which a semiconductor chip may be attached, and a packaging part to which a metal bump may be formed, and where the functional and packaging parts are arranged vertically, a characteristic change may occur. The characteristic change of the semiconductor chip may be for example, the degradation of a connection between a bump and an electrode, which may occur due to thermal stress generated between the semiconductor chip and the metal bump.

### SUMMARY OF THE INVENTION

Exemplary embodiments of the present invention may provide a semiconductor chip package which alleviates thermal stress that may occur between a semiconductor chip and a metal bump, and/or which strengthens shock resistance for the semiconductor chip package, and which has a structure that may be applicable to electronic devices of limited height.

Exemplary embodiments of the present invention may also provide a stacked semiconductor chip module that may be formed from a plurality of semiconductor chip packages.

An exemplary embodiment of the present invention may provide a semiconductor chip package including at least a first circuit board having a common plane divided into first and second areas and arranged in a horizontal direction. The first area may be designated only for functional material, while the second area may be designated only for packaging material. The semiconductor chip package may further provide at least one semiconductor chip mounted in the first area of the at least one circuit board, and may also provide a packaging material formed in the second area of the at least one circuit board. The packaging material may electrically connect the at least one semiconductor chip to an external terminal.

Exemplary embodiments of the present invention may provide a first circuit board which is formed of one of a one-sided printed circuit board (PCB), a double-sided PCB, a multi-sided PCB, and a flexible PCB.

Exemplary embodiments of the present invention may further provide the at least one semiconductor chip being electrically connected to the packaging material by metal wiring, and where the packaging material may be formed of a metal bump. The semiconductor chip may be electrically connected to the first circuit board by a bonding wire, and may be mounted to the at least one circuit board using a flip chip technique.

Exemplary embodiments of the present invention may further provide a semiconductor chip package including at least another circuit board, and where the at least one semiconductor chip may be disposed between two circuit boards, and may be electrically connected to the packaging material by a contact pad. The at least another circuit board may further include a plurality of passive components, which may be mounted in the first area of the at least one circuit board. The plurality of passive components may be in the same area as the at least one semiconductor chip and may be separated by an insulating layer disposed between the at least one semiconductor chip and the plurality of passive components. The insulating layer may be formed of a polyimide tape directly contacting the semiconductor chip, which may reduce the chances of a short occurring between the semiconductor chip and the plurality of passive components.

Exemplary embodiments of the present invention may further provide a semiconductor chip package which includes another plurality of passive components mounted on another surface in the first area of the first circuit board.

Exemplary embodiments of the present invention may provide a stacked semiconductor chip module which may include at least two circuit boards stacked together and/or aligned vertically, and may include a functional part having at least one semiconductor chip mounted on at least one circuit board, and may include a packaging part having a packaging material to electrically connect the semiconductor chip to an external terminal. The packaging part and the functional part may be separated into first and second areas. The first area may be designated only for functional material, while the second area may be designated only for packaging material.

Exemplary embodiments of the present invention may provide a thin package which may reduce a height of the semiconductor chip package, and/or may be formed to alleviate stress that may occur due to different thermal expansion coefficients of different materials used in semiconductor chip modules. A shock resistant characteristic of the semiconductor chip package may be strengthened by a solder ball, which may be composed of a metal bump, and which may be used as a packaging material in the semiconductor chip package.

### BRIEF DESCRIPTION OF THE DRAWINGS

Various features of the present invention will become readily apparent from the description of the exemplary embodiments that follow, with reference to the attached drawings in which:

FIG. 1 is a longitudinal sectional view illustrating a conventional structure of a ball grid array (BGA) package;

FIG. 2 illustrates a plane view of a semiconductor chip package according to an exemplary embodiment of the present invention;

FIG. 3 illustrates a cross-section of a semiconductor chip package stacked on a circuit board of an external terminal, according to an exemplary embodiment of the present invention;

FIG. 4 illustrates a longitudinal sectional view of a semiconductor chip package according to an exemplary embodiment of the present invention;

FIG. 5 illustrates a longitudinal sectional view of a semiconductor chip package according to another exemplary embodiment of the present invention;

FIG. 6 illustrates a longitudinal sectional view of a semiconductor chip package according to yet another exemplary embodiment of the present invention;

FIG. 7 illustrates a longitudinal sectional view of a semiconductor chip package according to yet still another exemplary embodiment of the present invention; and

FIG. 8 is a longitudinal sectional view of a stacked semiconductor chip package, according to an exemplary embodiment of the present invention.

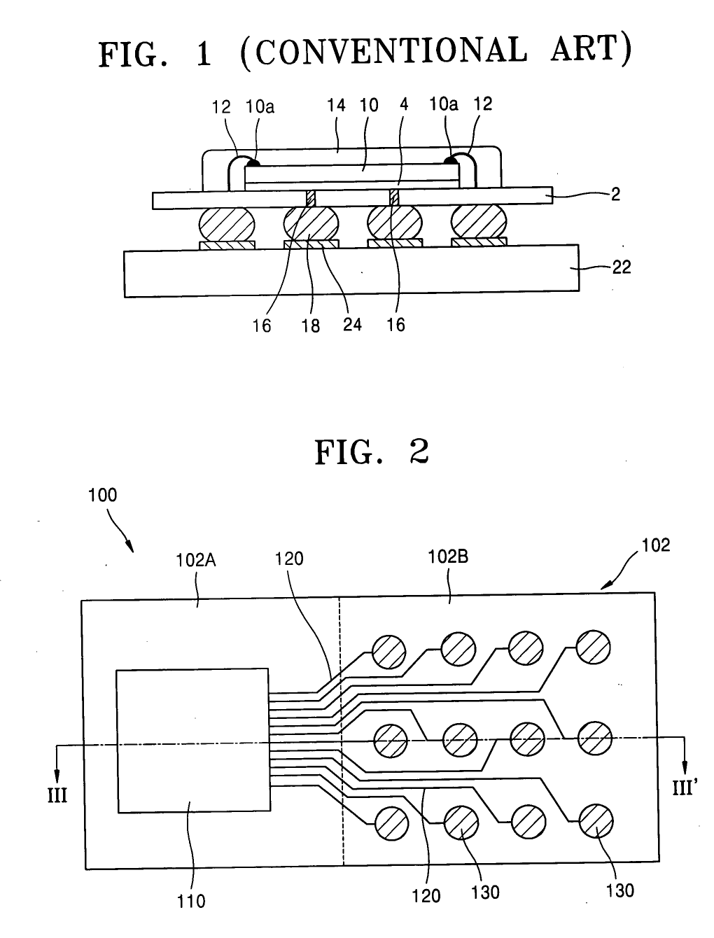

### DETAILED DESCRIPTION OF THE EXEMPLARY EMBODIMENTS OF THE PRESENT INVENTION

The present invention will be described more fully with reference to the accompanying drawings, in which exemplary embodiments of the invention are shown. It should be understood, however, that exemplary embodiments of the present invention described herein can be modified in form and detail without departing from the spirit and scope of the invention. Accordingly, the exemplary embodiments described herein are provided by way of example and not of limitation, and the scope of the present invention is not restricted to the particular embodiments described herein.

In particular, the relative thicknesses and positioning of layers or regions may be reduced or exaggerated for clarity. Further, a layer is considered as being formed “on” another layer or a substrate when formed either directly on the referenced layer or the substrate, or formed on other layers or patterns overlaying the referenced layer.

FIG. 2 illustrates a plane view of a semiconductor chip package according to an exemplary embodiment of the present invention.

Referring to FIG. 2, a semiconductor chip package 100 for example, may have a functional part in which a semiconductor chip 110 may be mounted, and a packaging part in which a packaging material may electrically connect the semiconductor chip 110 to an external terminal. The external terminal may include a metal bump 130 for example, formed by a solder ball. The functional and packaging parts may be horizontally disposed on a same or common plane of a first circuit board 102. The semiconductor chip 110 and the metal bump 130 may be electrically connected to each other via a metal wiring layer 120.

The semiconductor chip 110 and the metal bump 130 according to an exemplary embodiment of the present invention, may be formed on the same plane of the first circuit board 102, where the first circuit board 102 may be divided into a first area 102A and used as a functional part for example, and a second area 102B used as a packaging part for example, along a longitudinal direction. The metal bump 130 may be formed on the second area 102B.

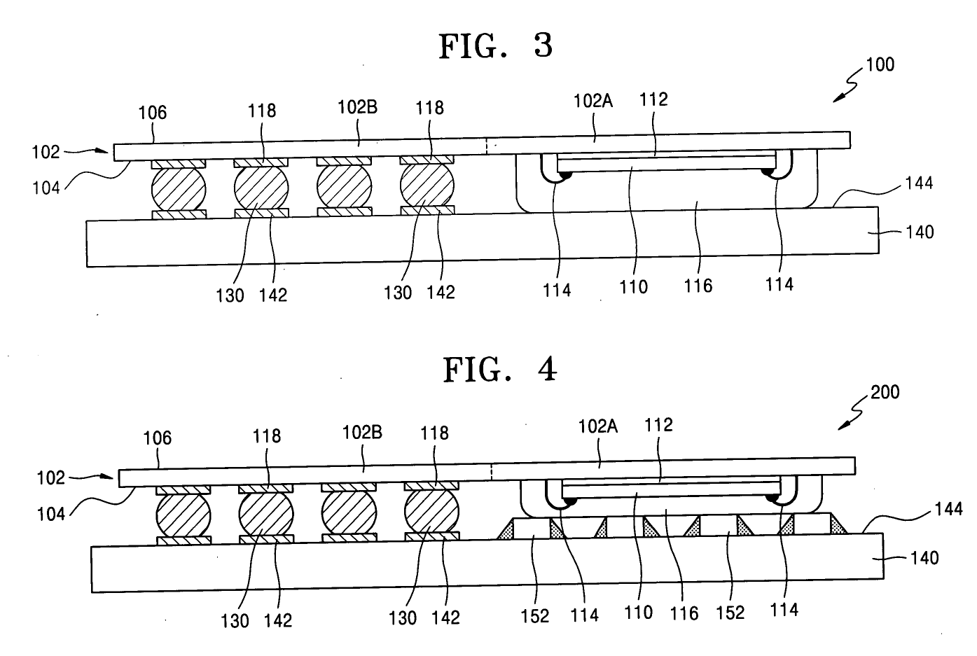

FIG. 3 illustrates a cross-section of a semiconductor chip package 100, which may be stacked on a second circuit board 140 of an external terminal, according to an exemplary embodiment of the present invention and illustrated in FIG. 2. FIG. 3 corresponds to a cross-section along line III-III as illustrated in FIG. 2.

Referring to FIG. 3, a first circuit board 102 of the semiconductor chip package 100 may be divided into a first area 102A, and a second area 102B arranged in a horizontal plane, and may include a first surface 104, a semiconductor chip 110, a metal bump 130, and a second surface 106 opposite of the first surface 104.

The first circuit board 102 may be formed from a one-sided printed circuit board (PCB), a double-sided PCB, and/or a multi-layered PCB.

The first area 102A may include a functional part of the first circuit board 102. The semiconductor chip 110 may be adhered to the first surface 104 by an insulating adhesive 112, and may be electrically connected to a metal wiring layer (not shown) on the first circuit board 102 by a bonding wire 114. The semiconductor chip 110 and the bonding wire 114 may be covered by a molding part 116 formed of a resin material such as an epoxy molding compound (EMC).

A second circuit board 140 may have a packaging surface 144, and which may face the first surface 104 of the first circuit board 102. The semiconductor chip 110 may be placed between the packaging surface 144 and the first surface 104.

The second area 102B may be referred to as the packaging part of the first circuit board 102, and may include a contact pad 118 formed on the first surface 104 of the second area 102B. Contact pad 118 may be electrically connected to the second circuit board 140 by a metal bump 130 and/or another contact pad 142, which may be formed on the packaging surface 144 of the second circuit board 140. The packaging surface 144 of the second circuit board 140 may include an area which faces the first surface 102A, and may be referred to as a functional part located in an area near or where the semiconductor chip 110 may be located. An area facing the second surface 102B may be referred to as a packaging part in which metal bump 130 may be located.

FIG. 4 is a longitudinal sectional view illustrating a semiconductor chip package 200 according to an exemplary embodiment of the present invention. In FIG. 4, identical reference numerals have been used for like elements illustrated in the exemplary embodiment of FIG. 3.

Semiconductor chip package 200, according to an exemplary embodiment of the present invention may have a similar structure when compared to the example semiconductor chip package 100 illustrated in FIG. 3. Semiconductor chip package 200 for example, may include a plurality of passive components 152, which may be formed on the packaging surface 144 of the second circuit board 140, and may face the first area 102A of the first circuit board 102.

Semiconductor chip package 200 may include a functional part having a semiconductor chip 110 for example, disposed vertically with respect to the plurality of passive components 152, which may be mounted together on a common plane. The passive components 152 may be formed in an area facing the first surface 102A and/or in the functional part of the first circuit board 102 along the packaging surface 144 of the second circuit board 140. A molding part 116 may be interposed to resonate between the semiconductor chip 110 and the passive components 152. Metal bump 118 may be connected to a contact pad 142 for example, located on or near the packing part of the first circuit board 102, among the packaging surface 144 of the second circuit board 140, and may be disposed in a position facing the second surface 1-02B, as illustrated in an exemplary embodiment of FIG. 4. The passive components 152 may be discrete passive components, for example capacitors, inductors, and/or resistors.

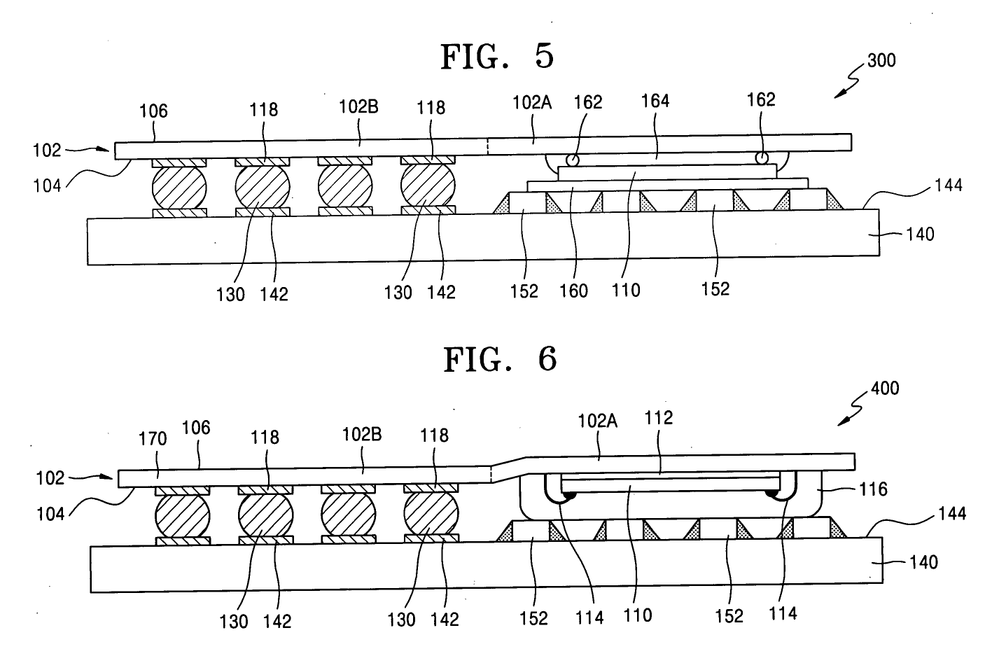

FIG. 5 illustrates a longitudinal sectional view of a semiconductor chip package according to an exemplary embodiment of the present invention. In FIG. 5, identical reference numerals have been used for like elements illustrated in the exemplary embodiment of FIG. 4.

Referring to FIG. 5, a semiconductor chip package 300 may have a similar structure when compared to the exemplary embodiment of FIG. 4. The semiconductor chip 110 of FIG. 5 may be mounted in the first area 102A of the first circuit board 102 by using a flip chip fabrication technique. The flip chip technique may include flipping the semiconductor chip, 110 for example, over so the connections on the semiconductor chip face downward. The flip chip method may provide a technique for reducing unnecessary wiring and packaging by placing the semiconductor chip connections in closer contact with external connections. The flip chip technique is well known to those skilled in the art of semiconductor fabrication, thus no further discussion regarding this technique may be necessary when describing the exemplary embodiments of the present invention.

The semiconductor chip 110 may be connected to an electrode (not shown) on the first circuit board 102 by a bump 162. A molding resin layer 164 such as an epoxy resin may be interposed for example in a gap between the first circuit board 102 and the semiconductor chip 110. The first circuit board 102 and the semiconductor chip 110 may be able to maintain a connection through the molding resin layer 164.

In an exemplary embodiment of FIG. 5, the semiconductor chip 110 may be mounted using a flip chip technique, and may have an exposed surface. In order to reduce the chance of a short occurring between the passive components 152 and the semiconductor chip 110, an insulating layer 160 may be interposed between the plurality of passive components 152 and the semiconductor chip 110. The insulating layer 160 may make direct contact with the semiconductor chip 110 and may be formed with a polyimide tape.

FIG. 6 illustrates a longitudinal sectional view of a semiconductor chip package 400, according to an exemplary embodiment of the present invention. In FIG. 6, identical reference numerals have been used for like elements illustrated in the exemplary embodiment of FIGS. 4-5.

Referring to FIG. 6, semiconductor chip package 400 may have a similar structure to the exemplary embodiment illustrated in FIG. 4. One exception may be that the first circuit board 102 is formed with a flexible printed circuit board material, for example a polyimide tape or PCB 170. If for example, the first circuit board 102 is formed with a flexible PCB 170, then a plurality of semiconductor chip packages 400 may be smoothly stacked together, thus a more integrated package may be formed.

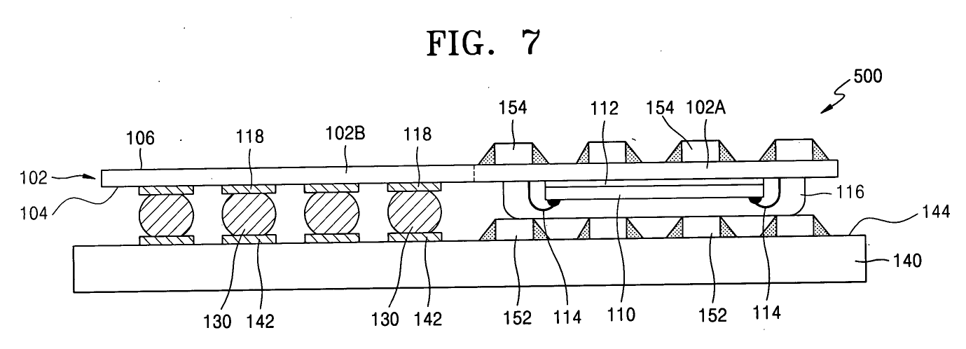

FIG. 7 illustrates a longitudinal sectional view of a semiconductor chip package 500, according to an exemplary embodiment of the present invention. In FIG. 7, identical reference numerals have been used for like elements illustrated in the exemplary embodiments of FIGS. 4-6.

Referring to FIG. 7, the semiconductor chip package 500 according to an exemplary embodiment of the present invention, may have a similar structure when compared to the exemplary embodiments of FIGS. 4-6. One exception for example may be another plurality of passive components 154, which may be mounted on the second surface 106 in the first area 102A of the first circuit board 102.

In the semiconductor chip package 500, the passive components 154 may be formed on a second surface 106 opposite from the first surface 104, where the semiconductor chip 110 may be mounted on the functional part of the first circuit board 102. The semiconductor chip 110 may be disposed vertically, with respect to the passive components 154. The passive components 154 may be discrete passive components, which may include capacitors, inductors, and/or resistors.

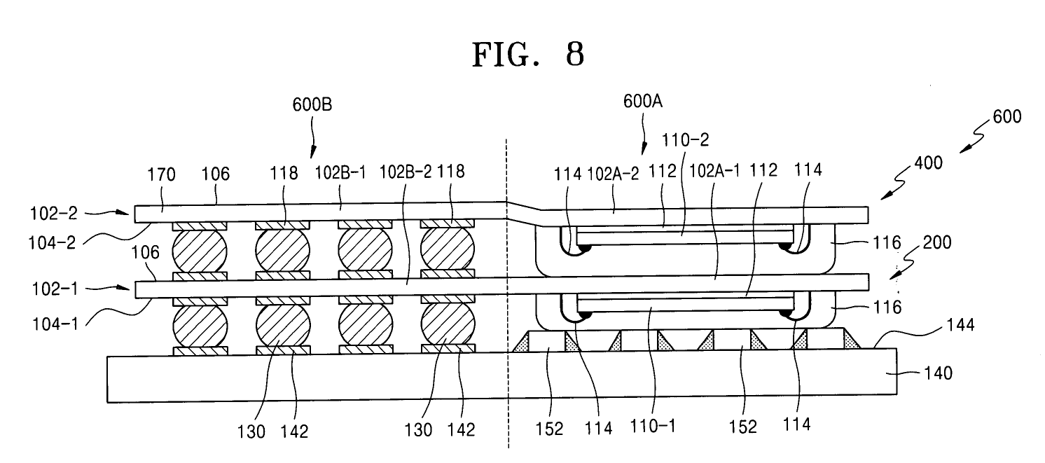

FIG. 8 illustrates a longitudinal sectional view of a stacked semiconductor chip package module according to an exemplary embodiment of the present invention. In FIG. 8, identical reference numerals have been used for like elements illustrated in the exemplary embodiments of FIG. 4-7.

Referring to FIG. 8, a semiconductor chip package stacked module 600 may be formed with a plurality of semiconductor chip packages 200 and 400, for example. The plurality of semiconductor chip packages 200 and 400 may be stacked together and include functional parts 102A(1-2) for example, on which the semiconductor chips 110(1-2) may be mounted. A packaging parts 102B(1-2) may include packaging material, for example metal bump 130 which may provide an electrical connection from the semiconductor chips 110(1-2) to an external terminal. The functional parts 102A(1-2) of the first circuit board 102-1 for example, may be placed within area 600A of the stacked semiconductor chip package module 600. The packaging part 102B of the first circuit board 102-1 for example, may be placed within area 600B of the stacked semiconductor chip package module 600. The functional parts 102A(1-2), which may be located in area 600A, and the packaging parts 102B(1-2), which may be located in area 600B of the stacked semiconductor chip package module 600.

The semiconductor chip packages 200 and 400 for example, which may be used to form the stacked semiconductor chip package module 600 are not limited to the elements illustrated in the exemplary embodiment of FIG. 8. Therefore, the stacked semiconductor chip package may be formed by selecting two or more of the same one and/or by combining the semiconductor chip packages 100, 200, 300, 400, 500 as presented in FIGS. 2-7.

The semiconductor chip package according to exemplary embodiments of the present invention may have functional and packaging parts in a circuit board. The functional and packaging parts may be spaced apart horizontally from each other, and on a same or common plane, and the semiconductor chip and the packaging material may be formed on the same plane of a common circuit board. In a stacked semiconductor chip package module, the functional and packaging parts may be arranged in a horizontal plane of a common circuit board. Therefore, the semiconductor chip package according to the exemplary embodiments of the present invention may form a thin package having reduced height, and may enhance packaging reliability. Thermal stress which may occur in individual elements may be alleviated by forming elements which have different thermal expansion coefficients. The height of a specific semiconductor chip package may be limited, and a shock resistant characteristic of the package may be strengthened by the size of the solder ball for example, which may be formed by a metal bump located in the packaging part. The stacked semiconductor chip package module may be formed by stacking the plurality of the semiconductor chip packages according to the exemplary embodiments of the present invention, and may be applied to thin electrical devices of limited height.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor chip package comprising:
at least one circuit board having a common plane area divided into at least a first and second area arranged in a horizontal plane, where the first area is designated for only functional material and the second area is designated for only packaging material.

2. The semiconductor chip package of claim 1, further comprising:
at least one semiconductor chip mounted in the first area of the at least one circuit board and at least one packaging material located in the second area of the at least one circuit board.

3. The semiconductor chip package of claim 1, further comprising:
at least one passive element mounted in the first area of the at least one circuit board.

4. The semiconductor chip package of claim 1, further comprising:
at least one semiconductor chip mounted in the first area of the at least one circuit board and at least one passive element mounted in the first area of the at least one circuit board aligned vertically with the at least one semiconductor chip.

5. The semiconductor chip package of claim 2, wherein the at least one semiconductor chip and the at least one packaging material are electrically connected by a conductive material to electrically connect the at least one semiconductor chip to an external terminal.

6. The semiconductor chip package of claim 2, wherein the at least one packaging material includes at least one metal bump.

7. The semiconductor chip package of claim 2, wherein the at least one semiconductor chip is electrically connected to the at least one circuit board by a bonding wire.

8. The semiconductor chip package of claim 1, wherein the at least one semiconductor chip is mounted in the first area of the at least one circuit board using a flip chip technique.

9. The semiconductor chip package of claim 1, wherein the at least one circuit board is formed with at least one of a one-sided printed circuit board, a double-sided printed circuit board, a multi-sided printed circuit board, and a flexible printed circuit board.

10. The semiconductor chip package of claim 2, further comprising:
at least another circuit board having a common plane area divided into at least a first and second area arranged in a horizontal plane, where the first area is designated for only functional material and the second area is designated for only packaging material, wherein the at least one semiconductor chip is disposed between the at least one circuit board and the at least another circuit board within the first area of the at least one circuit board and the at least another circuit board.

11. The semiconductor chip package of claim 10, further comprising:
at least two passive components mounted on the at least another circuit board within the first area of the at least one circuit board and the at least another circuit board.

12. The semiconductor chip package of claim 11, wherein the at least two passive components are discrete passive components.

13. The semiconductor chip package of claim 12, wherein the at least two passive components are separated from the at least one semiconductor chip by an insulating layer disposed between the at least one semiconductor chip and the at least two passive components.

14. The semiconductor chip package of claim 13, wherein the insulating layer is formed of an epoxy molding compound and provides a mold for the at least one semiconductor chip.

15. The semiconductor chip package of claim 13, wherein the insulating layer is formed of a polyimide tape in direct contact with the at least one semiconductor chip and which prevents or substantially prevents a short from occurring between the at least one semiconductor chip and the at least two passive components.

16. The semiconductor chip package of claim 11, further comprising at least two passive components mounted on the at least one circuit board and in the first area of the at least one circuit board.

17. The semiconductor chip package of claim 10, further comprising:
at least another semiconductor chip mounted on the at least another circuit board and within the first area of the at least one circuit board and the at least another circuit board; and
at least one packaging material disposed between the at least one circuit board and the at least another circuit board within the first area of the at least one circuit board and the at least another circuit board wherein the at least one circuit board and the at least another circuit board are arranged together vertically.

18. The semiconductor chip package of claim 17, wherein the at least one circuit board and the at least another circuit board are formed with one of a one-sided printed circuit board, a double-sided printed circuit board, a multi-sided printed circuit board, and a flexible printed circuit board.

19. The semiconductor chip package of claim 17, further comprising:
at least two passive components formed on at least one of the at least one circuit board and the at least another circuit board and within the first area of the at least one circuit board and the at least another circuit board.

20. The stacked semiconductor chip package of claim 17, wherein at least one of the at least one circuit board and the at least another circuit board is composed of a flexible substrate.

21. A method for forming a semiconductor chip package comprising:
mounting at least one semiconductor chip in a first area of a first circuit board, wherein the first circuit board includes a common plane area divided into at least a first and second area arranged in a horizontal plane, where the first area is designated for only functional material and the second area is designated for only packaging material; and
forming at least one packaging material in the second area of the first circuit board to electrically connect the at least one semiconductor chip in the first area of the first circuit board to an external terminal.

22. The method of claim 21, further comprising:
stacking the first circuit board on at least another circuit board, said stacked circuit boards each having at least one semiconductor chip mounted in the first area, where each of the stacked circuit boards are aligned vertically; and
wherein each of the stacked circuit boards contain packing material in the second area to electrically connect the respective semiconductor chips of the stacked circuit boards to an external terminal.

23. A method of forming the semiconductor chip package of claim 1.
